(19) United States
(12) Patent Application Publication
(10) Pub. No.: US 2011/0215424 A1
(43) Pub. Date: Sep. 8, 2011

(54) SEMICONDUCTOR DEVICE AND MANUFACTURING METHOD THEREOF

(75) Inventor: Yoshihiro SATO, Kanagawa (JP)

(73) Assignee: FURUKAWA ELECTRIC CO., LTD., Tokyo (JP)

(21) Appl. No.: 13/042,365

(22) Filed: Mar. 7, 2011

(30) Foreign Application Priority Data
Mar. 8, 2010 (JP) 2010-050416

(51) Int. Cl. H01L 29/78; H01L 21/336

(52) U.S. Cl. 257/409; 438/285; 257/E29.271; 257/E21.409

(57) ABSTRACT

A semiconductor device includes a semiconductor operating layer that is made of group-III nitride-based compound semiconductor and a first electrode and a second electrode formed on the semiconductor operating layer. Sheet carrier density of the semiconductor operating layer is no less than 1×10¹² cm⁻² and no greater than 5×10¹³ cm⁻². Dislocation density of the semiconductor operating layer is no less than 1×10⁸ cm⁻² and no greater than 5×10⁸ cm⁻².

### BACKGROUND

1. Technical Field

The present invention relates to a semiconductor device made of group-III nitride-based compound semiconductor used as a power electronic device or as a high-frequency amplifying device and a method of manufacturing the semiconductor device.

2. Related Art

A wide band gap semiconductor can be exemplified by group-III nitride-based compound semiconductor, and has high breakdown voltage (withstand voltage), high electron mobility, and high thermal conductivity. Therefore, such a wide band gap semiconductor is extremely useful as a material in semiconductor devices used in ways that involve high power, high frequency, or high temperature environments. For example, a field effect transistor (FET) having an AlGaN/GaN heterojunction structure is polarized due to the Piezo effect, and 2-dimensional electron gas (2DEG) is formed at the interface. This 2DEG has high electron mobility and high carrier density, and therefore this FET can be expected for use as a power switching device having low ON resistance and high-speed switching characteristics.

An AlGaN/GaN HEMT is widely studied as an FET using the group-III nitride-based compound semiconductor, however, this type of FET has a low threshold voltage around +1 V. A MOSFET using the group-III nitride-based compound semiconductor is also studied, and devices with high mobility or withstand voltages near 1000 V have been developed. However, a device realizing both high mobility and high withstand voltage has yet to be achieved.

In FETs and diodes, a drift layer through which the carriers move and a field reducing layer desirably have as high a resistance as possible in an OFF state and as low a resistance as possible in an ON state, which can be expressed as a trade-off relationship. In order to lower the resistance of the field reducing layer and the drift layer, it is desired to achieve an increase in carrier mobility that does not directly contribute to the operation in the OFF state.

Patent Document 1 describes a MOSFET using group-III nitride-based compound semiconductor that has high withstand voltage and large current, and that performs a normally-off operation. This is achieved by setting the sheet carrier concentration of the field reducing region, which is formed adjacent to a drain side contact region, in a range no less than 1×10¹² cm⁻² and no greater than 5×10¹³ cm⁻².
Patent Document 1: Japanese Patent Application Laid-open No. 2008-311392

Patent Document 1 describes how to realize a normally-off transistor with a high withstand voltage by setting the sheet carrier density of the reduced surface field (RESURF) region in a suitable range. However, this device does not realize both high mobility and high withstand voltage. Since the mobility in a single-crystal semiconductor is inversely proportional to the sheet carrier density, the mobility and the sheet carrier density cannot be independently controlled.

### SUMMARY

The present invention has been achieved in view of the above aspects, and it is an object of the present invention to provide a semiconductor device made of group-III nitride-based compound semiconductor and capable of operating with a large current, and that achieves both high mobility and high withstand voltage.

In order to solve the above problems, inventors of the present invention thought that, since the group-III nitride-based compound semiconductor, exemplified by GaN, has high dislocation density, it would be appropriate to treat the group-III nitride-based compound semiconductor as a polycrystal. In the case of polycrystalline semiconductor, the mobility depends not only on the sheet carrier density, but also on the dislocation density and the impurity density. Therefore, the inventors of the present invention found that, even when the impurity density and the sheet carrier density are determined based on the ON resistance and the withstand voltage, the group-III nitride-based compound semiconductor with high mobility can be obtained by controlling a value of the dislocation density.

According to a first aspect of the present invention, there is provided a semiconductor device including a semiconductor operating layer that is made of group-III nitride-based compound semiconductor and has a sheet carrier density no less than 1×10¹² cm⁻² and no greater than 5×10¹³ cm⁻² and a first electrode and a second electrode formed on the semiconductor operating layer. Dislocation density of the semiconductor operating layer is no less than 1×10⁸ cm⁻² and no greater than 5×10⁸ cm⁻².

According to another aspect of the present invention, in the semiconductor device, the group-III nitride-based compound semiconductor is made of AlₓIn_{y}Ga_{1-x-y}N, where 0≦x≦1, 0≦y≦1, and 0≦x+y≦1.

According to another aspect of the present invention, in the semiconductor device, the first electrode is a Schottky electrode and the second electrode is an ohmic electrode.

According to another aspect of the present invention, in the semiconductor device, the first electrode is a source electrode, the second electrode is a drain electrode, and the semiconductor device further includes an insulating film that is formed on the semiconductor operating layer between the source electrode and the drain electrode and a gate electrode formed on the insulating film.

According to a third aspect of the present invention, provided is a method of manufacturing a semiconductor device that includes forming, on a substrate, a semiconductor operating layer that is made of group-III nitride-based compound semiconductor with sheet carrier density no less than 1×10¹² cm⁻² and no greater than 5×10¹³ cm⁻², and forming a first electrode and a second electrode on the semiconductor operating layer. Forming the semiconductor operating layer includes forming a dislocation-density control layer controlling dislocation density of the semiconductor operating layer to be no less than 1×10⁸ cm⁻² and no greater than 5×10⁸ cm⁻².

The summary clause does not necessarily describe all necessary features of the embodiments of the present invention. The present invention may also be a sub-combination of the features described above.

### EFFECT OF THE INVENTION

The present invention can provide a semiconductor device made of group-III nitride-based compound semiconductor and capable of operating with a large current, and that achieves both high mobility and high withstand voltage.

### BRIEF DESCRIPTION OF THE DRAWINGS

FIG. 1 is a schematic cross-sectional view of a semiconductor device according to a first embodiment of the present invention.

FIG. 2 is a graph showing a relationship between carrier mobility and sheet carrier density of a field reducing region in the semiconductor device according to the first embodiment.

FIG. 3A is a schematic cross-sectional view of a step for forming a buffer layer and a semiconductor operating layer of the semiconductor device according to the first embodiment.

FIG. 3B is a schematic cross-sectional view of a step for forming a first ion implantation mask of the semiconductor device according to the first embodiment.

FIG. 3C is a schematic cross-sectional view of a step for forming a first implantation region of the semiconductor device according to the first embodiment.

FIG. 3D is a schematic cross-sectional view of a step for forming a second ion implantation mask, a second implantation region, and a second implantation region of the semiconductor device according to the first embodiment.

FIG. 4A is a schematic cross-sectional view of a step for forming the field reducing region, a source electrode side contact region, a drain electrode side contact region, an insulating film, a source electrode and a drain electrode of the semiconductor device according to the first embodiment.

FIG. 4B is a schematic cross-sectional view of a step for forming a gate electrode of the semiconductor device according to the first embodiment.

FIG. 5A is a schematic cross-sectional view of a step for forming a low-temperature growth layer of a dislocation decreasing layer.

FIG. 5B is a schematic cross-sectional view of a step for forming a roughening layer of a dislocation decreasing layer.

FIG. 5C is a schematic cross-sectional view of a step for forming a flattening layer of a dislocation decreasing layer.

FIG. 6 is a schematic cross-sectional view of a bent state of dislocations passing through the dislocation decreasing layer.

FIG. 7 is a schematic cross-sectional view of a semiconductor device according to a second embodiment of the present invention.

### DESCRIPTION OF EXEMPLARY EMBODIMENTS

Exemplary embodiments of a semiconductor device and a manufacturing method thereof according to the present invention will be described in detail below with reference to accompanying drawings. However, the embodiments should not be construed to limit the invention. All the combinations of the features described in the embodiments are not necessarily essential to means provided by aspects of the invention.

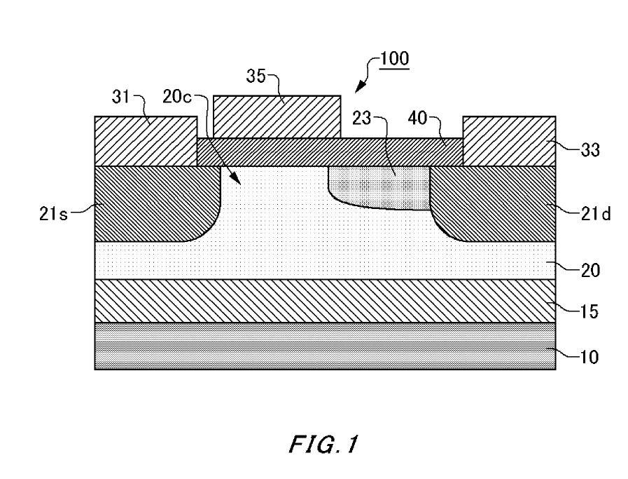

FIG. 1 is a schematic cross-sectional view of the semiconductor device 100 according to a first embodiment of the present invention. As shown in FIG. 1, the semiconductor device 100 includes a semiconductor operating layer 20 made of group-III nitride-based compound semiconductor and formed above a substrate 10 with a buffer layer 15 interposed therebetween. The semiconductor device 100 further includes a source electrode 31 and a drain electrode 33 on the semiconductor operating layer 20, with a predetermined space therebetween. A gate electrode 35 may be formed on an insulating film 40 between the source electrode 31 and the drain electrode 33. In other words, the semiconductor device 100 is a so-called MOSFET.

The semiconductor operating layer 20 may be p-type (acceptor concentration no less than 1×10¹⁵ cm⁻³ and no greater than 5×10¹⁷ cm⁻³) or undoped gallium nitride (GaN). The semiconductor operating layer 20 may include a source electrode 31 side contact region 21s and a drain electrode 33 side contact region 21d made of n⁺-type (donor concentration no less than 1×10¹⁹ cm⁻³ and no greater than 1×10²¹ cm⁻³) GaN and formed in the surface at the positions where the source electrode 31 and the drain electrode 33 are formed. Furthermore, a field reducing region 23 made of n⁻-type GaN is formed adjacent to the drain electrode 33 side contact region 21d.

The field reducing region 23 is formed in the semiconductor operating layer 20 between the positions where the gate electrode 35 and the drain electrode 33 are formed. Here, the source electrode 31 and the drain electrode 33 are both ohmic electrodes.

The field reducing region 23 and the source electrode 31 side contact region 21s are formed with a predetermined space therebetween. The region between the field reducing region 23 and the source electrode 31 side contact region 21s is the channel region 20c. The gate electrode 35 may be formed above the portion of the semiconductor operating layer 20 corresponding to the channel region 20c, with the insulating film 40 interposed therebetween. The channel is formed by focusing electrons (not shown) serving as negative carriers in the channel region 20, and this focusing is achieved by applying a forward bias, i.e. a positive voltage of several V, to the gate electrode 35. As a result, a current path is formed via which electrons pass sequentially through the source electrode 31, the source electrode 31 side contact region 21s, the channel region 20c, the field reducing region 23, the drain electrode 33 side contact region 21d, and the drain electrode 33.

At this time, the field reducing region 23 is formed such that the carrier concentration therein is lower than the carrier concentration in the drain electrode 33 side contact region 21d adjacent thereto. As a result, when a high voltage is applied between the source electrode 31 and the drain electrode 33, the electric field is dispersed in the current path within the semiconductor operating layer 20 between the channel region 20c and the field reducing region 23 and between the field reducing region 23 and the drain electrode side contact region 21d. As a result, insulation breakdown can be suppressed.

Here, the sheet carrier density of the field reducing region 23 is preferably no less than 1×10¹² cm⁻² and no greater than 5×10¹³ cm⁻². If the sheet carrier density is less than 1×10¹² cm⁻², the electric field is focused in the end of the drain electrode 33 on the gate electrode 35 side, which makes this region prone to insulation breakdown. If the sheet carrier density is greater than 5×10¹³ cm⁻², the electric field is focused in the end of the gate electrode 35 on the drain electrode 33 side, which makes this region prone to insulation breakdown.

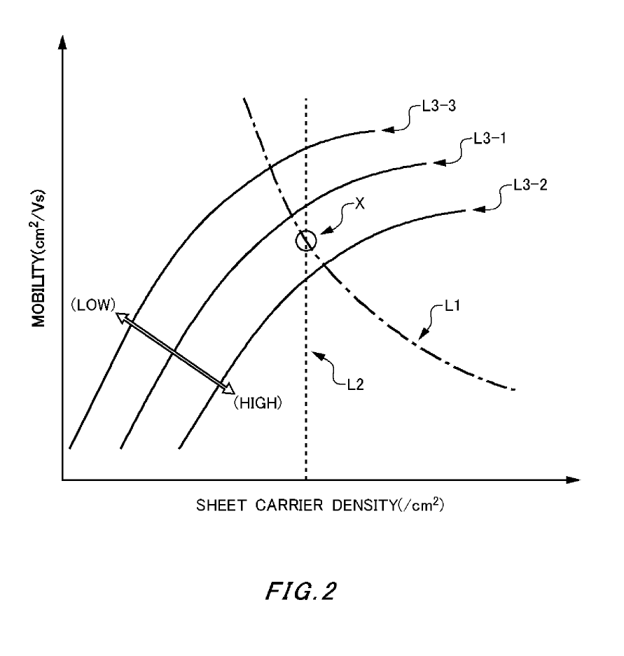

FIG. 2 is a graph showing a relationship between carrier mobility and sheet carrier density of the field reducing region 23 in the semiconductor device 100 according to the first embodiment. As shown in FIG. 2, in a polycrystalline semiconductor, the mobility is affected by the dispersion L3 (L3-1 to L3-3) caused by dislocations and the dispersion L1 caused by impurities of the field reducing region 23. The dispersion caused by dislocations causes the mobility to be low when the dislocation density is high (L3-2) and to be high when the dislocation density is low (L3-3).

As described above, there is a range that is preferable for the sheet carrier density. Accordingly, the mobility at a given sheet carrier density L2 can be shown by the intersection between L2 and L1 or the intersection between L2 and L3. In the example shown in FIG. 2, the mobility is the intersection X between L2 and L1.

Here, high mobility can be achieved by controlling the dislocation density such that L3 passes through the intersection X. When the intersection between L3 and L2 is used, the mobility can be improved by lowering the dislocation density. In other words, by controlling the dislocation density such that L1, L2, and L3 all pass through a single point, the dispersion caused by dislocations and the dispersion caused by impurities can be minimized, thereby achieving high mobility. Accordingly, by setting the dislocation density according to the intersection X with regard to the sheet carrier density vs. mobility characteristic of group-III nitride-based compound semiconductor, the dislocation mobility of the field reducing region 23 made of the group-III nitride-based compound semiconductor can be kept low. As a result, the mobility of the field reducing region 23 is high. The intersection X is the intersection between a curve representing the effect of impurity dispersion and a straight line representing the sheet carrier density.

Here, the dislocation density represents a measurement of the number of edge dislocations per unit area in the crystal based on dark-field images obtained by a transmission electron microscope (TEM) providing excitation from the [10-10] direction.

TABLE I

| | | | | | | |
|---|---|---|---|---|---|---|
| EDGE DISLOCATION | 1 | 3 | 5 | 8 | 9 | 10 |
| DENSITY (×10⁸ cm⁻²) | | | | | | |
| MOBILITY (cm²/Vs) | 378 | 392 | 366 | 168 | 105 | 21 |

Table I shows a relationship between the dislocation density and the mobility when the carrier density of the field reducing region 23 is 5×10¹⁷ cm⁻³, i.e. when the sheet carrier density is 5×10¹² cm⁻².

To achieve a preferable sheet carrier density and impurity diffusion limit based on the above, the dislocation density of the field reducing region 23 of the semiconductor device 100 according to the first embodiment is preferably no less than 1×10⁸ cm⁻² and no greater than 5×10⁸ cm⁻².

If the dislocation density of the field reducing region 23 is greater than 5×10⁸ cm⁻², the maximum mobility is low. If the dislocation density of the field reducing region 23 is less than 1×10⁸ cm⁻², the withstand voltage of the field reducing region 23 drops. The dislocation density of the field reducing region 23 is preferably no less than 1×10⁸ cm⁻² and no greater than 3×10⁸ cm⁻².

The sheet carrier density of the field reducing region 23 is preferably no less than 1×10¹² cm⁻² and no greater than 5×10¹³ cm⁻², and the dislocation density of the field reducing region 23 is preferably no less than 1×10⁸ cm⁻² and no greater than 5×10⁸ cm⁻². When the sheet carrier density of the field reducing region 23 is no less than 1 and no greater than 5×10¹³ cm⁻², the maximum mobility is lowered if the dislocation density of the field reducing region 23 is greater than 5×10⁸ cm⁻². When the sheet carrier density of the field reducing region 23 is no less than 1×10¹² cm⁻² and no greater than 5×10¹³ cm⁻², the withstand voltage of the field reducing region 23 drops if the dislocation density of the field reducing region 23 is less than 1×10⁸ cm⁻². The sheet carrier density of the field reducing region 23 is more preferably no less than 1×10¹² cm⁻² and no greater than 3×10¹³ cm⁻², and the dislocation density of the field reducing region 23 is more preferably no less than 1×10⁸ cm⁻² and no greater than 5×10⁸ cm⁻². As described above, the present invention can be used to obtain a MOSFET with high mobility and high withstand voltage that can operate with a large current.

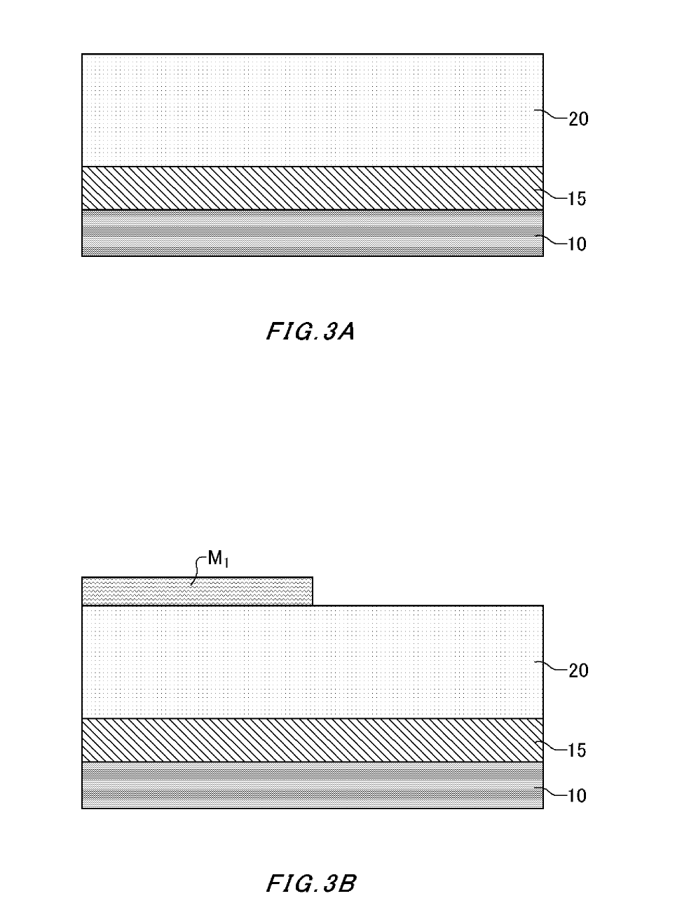

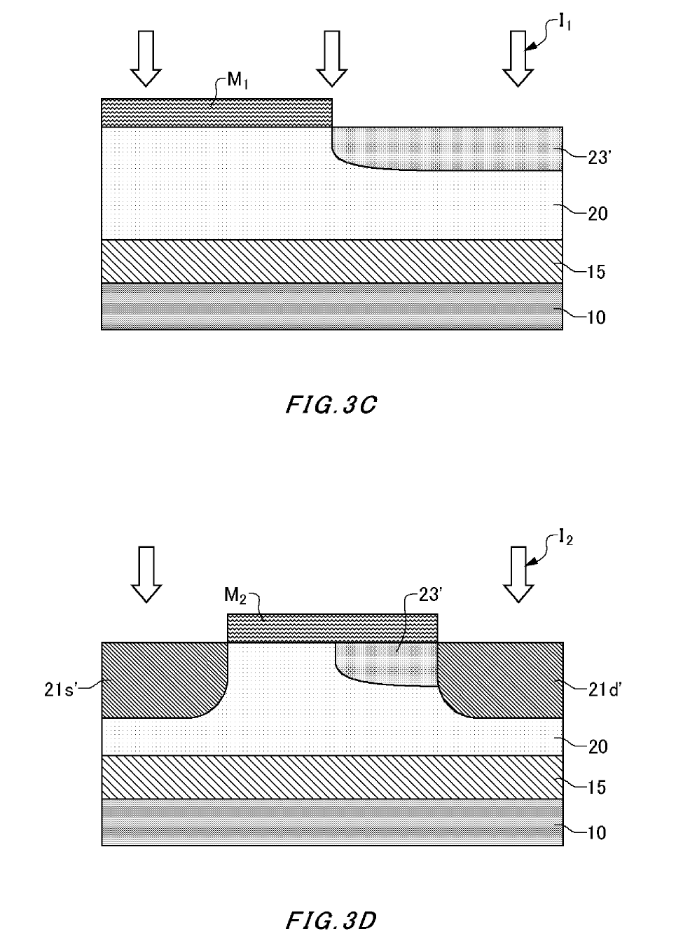

The following references FIGS. 3A to 3D, 4A, and 4B to describe a method of manufacturing the semiconductor device 100 according to the first embodiment. Components in FIGS. 3A to 3D, 4A, and 4B having the same reference numerals as components in FIG. 1 may have the same function and configuration.

First, the buffer layer 15 may be epitaxially grown on the substrate 10 using MOCVD. For example, trimethyl gallium TMGa, trimethyl aluminum TMAl, and ammonia NH₃ may be used as a raw material gas to form the buffer layer 15 on the substrate 10, which may be made of silicon and have the (111) plane as a primary surface, by repeatedly layering composite layers of AlN/GaN.

Next, the semiconductor operating layer 20 may be epitaxially grown on the buffer layer 15 using MOCVD. For example, the semiconductor operating layer 20 may be made of GaN using TMGa and NH₃ as the raw material gas, as shown in FIG. 3A.

Next, 500 nm of SiO₂ are formed on the surface of the semiconductor operating layer 20 using plasma chemical vapor deposition (PCVD). The SiO₂ is removed from the portion that will become the field reducing region and the portion that will become the drain electrode side contact layer, and a first ion implantation mask M₁ for forming the field reducing region is formed, as shown in FIG. 3B. Here, silane (SiH₄) and nitrous oxide, such as dinitrous monoxide N₂O, can be used as the raw material for the SiO₂.

Next, a first implantation region 23′ is formed by doping Si-ions I₁ using ion implantation in portions of the semiconductor operating layer 20 where the first ion implantation mask M₁ is not disposed, as shown in FIG. 3C. At this time, conditions such as the implantation energy and the dose amount are adjusted such that the ion implantation depth is 50 nm and the sheet carrier density of the ion implantation region is 1×10¹² cm⁻².

Next, the first ion implantation mask M₁ is removed, and a second ion implantation mask M₂ for forming the contact region is formed in the region where the channel and the field reducing region will be formed. The second ion implantation mask M₂ may be made of SiO₂ in the same way as the first ion implantation mask M₁, and may have a thickness of approximately 1 μm.

Second implantation regions 21s′ and 21d′ are formed by doping Si-ions I₂ using ion implantation in portions of the semiconductor operating layer 20 where the second ion mask M₂ is not disposed, as shown in FIG. 3D. The second implantation regions 21s′ and 21d′ are annealed, as described further below, to form the source electrode 31 side contact region 21s and the drain electrode 33 side contact region 21d. The ion implantation amount of the second implantation regions 21s′ and 21d′ are set such that the sheet carrier density of each of the source electrode 31 side contact region 21s and the drain electrode 33 side contact region 21d is 1×10¹⁶ cm⁻².

Next, the second ion implantation mask M₂ is removed. After this, an annealing mask (not shown) made of SiO₂ is formed over the entire surface of the semiconductor operating layer 20, and annealing is performed for 30 seconds at 1200° C. As a result, the implanted impurities (Si-ions) are activated, thereby forming the field reducing region 23, the source electrode side contact region 21s, and the drain electrode side contact region 21d, as shown in FIG. 4A.

Next, the annealing mask is removed. After this, the insulating film 40 made of SiO₂ is formed on the channel and the field reducing region 23, and photolithography is used to sequentially layer Ti and Al on the source electrode 31 side contact region 21s and the drain electrode 33 side contact region 21d, thereby forming the source electrode 31 and the drain electrode 33 as shown in FIG. 4A.

After this, a liftoff technique or the like is used to form the gate electrode 35 on the insulating film 40, as shown in FIG. 4B. The gate electrode 35 may be formed by layering a layer made of Au on a layer made of Ni. The gate electrode 35 may be formed of polysilicon.

The semiconductor device 100 according to the first embodiment is manufactured as a result of the above process.

The following describes an exemplary method for controlling the dislocation density of the semiconductor operating layer 20. The dislocation density of the semiconductor operating layer 20 can be controlled by forming a dislocation-density control layer 50 within the semiconductor operating layer 20 or within a layer formed on the substrate side of the semiconductor operating layer 20, e.g. within the buffer layer 15.

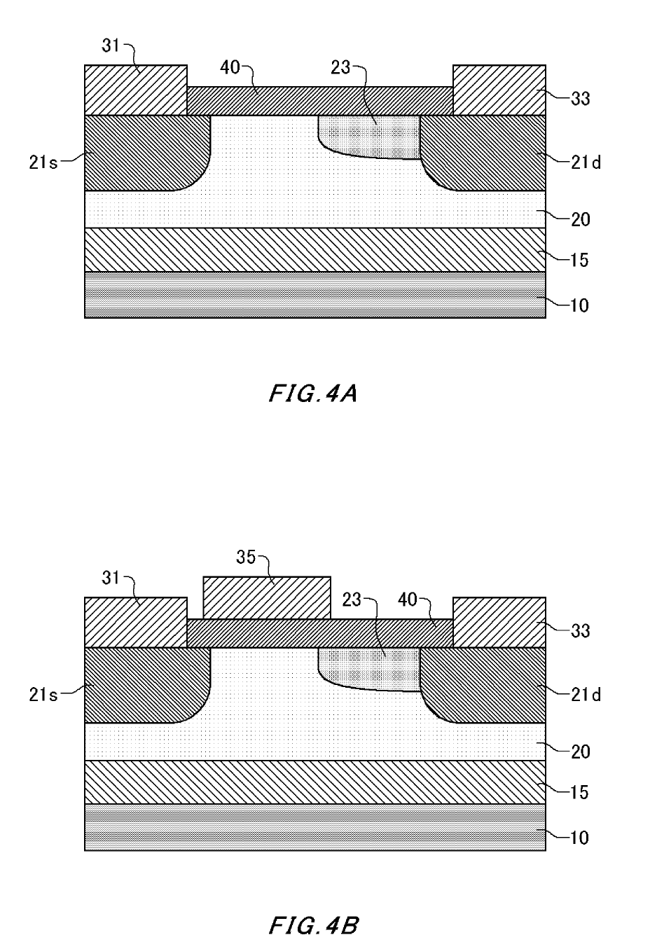

FIGS. 5A to 5C are schematic cross-sectional views of steps for forming the dislocation-density control layer 50 on the buffer layer 15. Components in FIGS. 5A to 5C having the same reference numerals as components in FIGS. 1, 3A to 3D, 4A, and 4B may have the same function and configuration. The dislocation-density control layer 50 may include a low-temperature growth layer 51, a roughening layer 53, and a flattening layer 55. First, as shown in FIG. 5A, the low-temperature growth layer 51 may be epitaxially grown on the buffer layer 15 using MOCVD. For example, a layer made of GaN with a thickness of 40 nm may be grown as the low-temperature growth layer 51 with a substrate temperature of 500° C. and a growth pressure of 500 Torr. The low-temperature growth layer 51 serves as the nucleus when growing the roughening layer 53 on the low-temperature growth layer 51.

Next, as shown in FIG. 5B, the roughening layer 53 may be epitaxially grown on the low-temperature growth layer 51 using MOCVD. For example, a layer made of GaN with an average thickness of approximately 200 nm may be grown on the low-temperature growth layer 51 as the roughening layer 53 with a substrate temperature of 900° C. and a growth pressure of 500 Torr. The roughening layer 53 may be crystal-grown under GaN growth conditions that are adjusted to create an uneven surface.

Next, as shown in FIG. 5C, the flattening layer 55 may be epitaxially grown on the roughening layer 53 using MOCVD. For example, a layer made of GaN with an average thickness of approximately 1000 nm may be formed on the roughening layer 53 as the flattening layer 55 in order to even out the unevenness, with a substrate temperature of 1050° C. and a growth pressure of 100 Torr. The interface between the roughening layer 53 and the flattening layer 55 may include surfaces parallel to the surface of the substrate 10 or the low-temperature growth layer 51 and surfaces that are inclined by more than 0 degrees and less than 90 degrees with respect to the surface of the substrate 10 or the low-temperature growth layer 51. The maximum valley depth P_{V} of the cross-sectional uneven surface of the interface between the roughening layer 53 and the flattening layer 55 may be from 10 nm to 10,000 nm, for example.

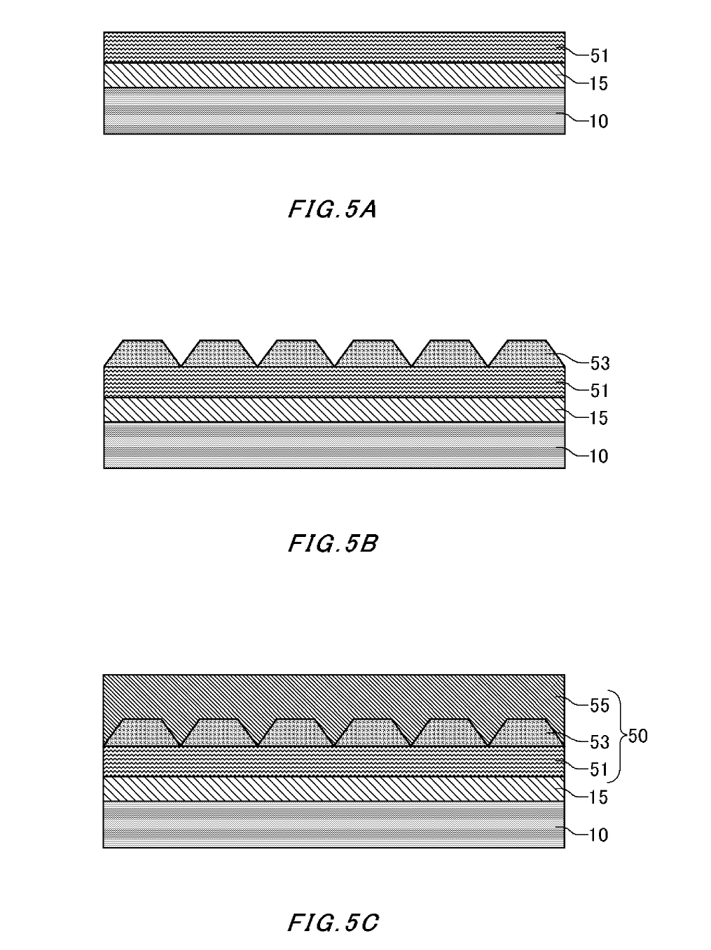

As shown in FIG. 6, dislocations D₁ to D₄ at the interface between the buffer layer and the substrate (not shown) extend upward in the layer direction of the low-temperature growth layer 51 and the roughening layer 53. The dislocations D₂ and D₄ bend at the inclined surfaces of the uneven interface, i.e. the surfaces that are inclined with respect to the primary surface of the substrate. The dislocations D₃ and D₄ extend through the flattening layer 55 to the surface directly above the dislocation-density control layer 50, i.e. the surface of the buffer layer or semiconductor operating layer (not shown).

Here, the dislocations D₁ and D₂ have Burgers vectors that are the inverse of each other. The dislocations D₁ and D₂ also extend upward through the low-temperature growth layer 51 and the roughening layer 53. The dislocation D₂ bends at the inclined surface of the uneven interface in the roughening layer 53 and combines with the dislocation D₁ at a point P in the flattening layer 55. When the dislocations D₁ and D₂ have Burgers vectors that are the inverse of each other, the dislocations D₁ and D₂ cancel each other out at the point P. Even if the dislocations D₁ and D₂ do not cancel each other out at the point P, the magnitude of their Burgers vectors are decreased, and therefore the dislocations D₁ and D₂ are easier to cancel out while extending further upward.

In other words, the dislocation-density control layer 50 bends the dislocations with an uneven interface to increase the probability that dislocations will combine with each other. In this way, the dislocation-density control layer 50 can cause dislocations having inverse Burgers vectors to cancel each other out or to have decreased magnitude.

The percentage by which the dislocations are reduced in the flattening layer 55 can be changed by adjusting growth conditions of the roughening layer 53, such as the growth pressure, to change the percentage of inclined surfaces in the uneven structure of the roughening layer 53. As a result, the density of the dislocations reaching the buffer layer 15 and/or the semiconductor operating layer 20 formed on the flattening layer 55 can be controlled.

The steps described above can be altered without deviating from the scope of the present invention.

In the above description, after the portion corresponding to the field reducing region 23 is formed, the portions corresponding to the source electrode 31 side contact region 21s and the drain electrode 33 side contact region 21d are formed. The steps may be performed in the opposite order. In other words, the portion corresponding to the field reducing region 23 may be formed after forming the portions corresponding to the source electrode 31 side contact region 21s and the drain electrode 33 side contact region 21d. Furthermore, the source electrode 31 and the drain electrode 33 are exemplified as having Ti/AL layered structures, but other material may be used that can achieve ohmic contact with the source electrode 31 side contact region 21s and the drain electrode 33 side contact region 21d. The uneven surface of the roughening layer 53 may be formed by machining, wet etching, or dry etching the surface of the roughening layer 53. The entire surface of the roughening layer 53 may be uneven. The uneven portions may be formed at random or at regular intervals. The roughening layer 53 may include an uneven portion only on the portion of the surface corresponding to where the semiconductor device 100 is formed.

The method for controlling the dislocation density is not limited to using a layer that controls the dislocation, as described above. For example, a mask having a plurality of openings may be formed on the growth surface of the substrate and epitaxial lateral overgrowth (ELOG) may be performed from the substrate exposed by the openings, thereby forming an uneven layer and controlling the dislocation density. This mask may be made of SiO₂.

In the above description, the dislocation-density control layer 50 and the buffer layer 15 are different layers. However, the dislocation-density control layer 50 may be formed within the buffer layer 15. For example, the dislocation-density control layer 50 may be formed by sequentially growing the low-temperature growth layer 51, the roughening layer 53, and the flattening layer 55 on the substrate, and the buffer layer 15 may be formed on the dislocation-density control layer 50.

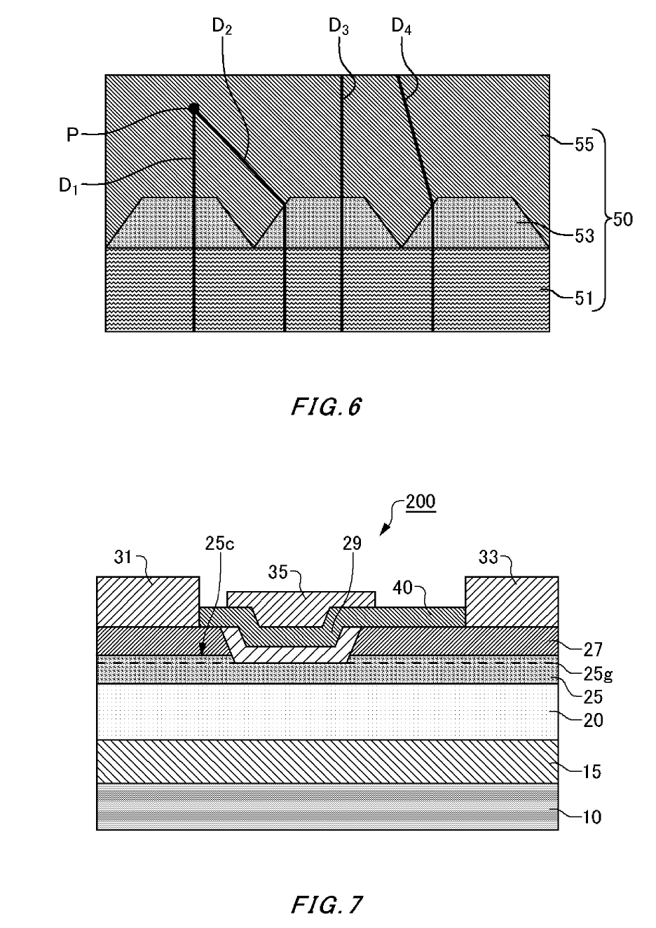

The following describes a semiconductor device 200 according to a second embodiment of the present invention. FIG. 7 is a schematic cross-sectional view of the semiconductor device 200 according to the second embodiment. Components in FIG. 7 having the same reference numerals as components in FIG. 1 may have the same function and configuration. In the same manner as the semiconductor device 100, the semiconductor device 200 includes the buffer layer 15 and the semiconductor operating layer 20 on the substrate 10. Furthermore, the semiconductor device 200 includes a drift layer 25 made of undoped GaN or GaN with a lower acceptor concentration than the semiconductor operating layer 20 formed on the semiconductor operating layer 20. The semiconductor device 200 may include an electron supplying layer 27 made of AlGaN on the drift layer 25.

The drift layer 25 operates as the field reducing region in the semiconductor device 200 according to the second embodiment, and so may be formed to have a dislocation density no less than 1×10⁸ cm⁻² and no greater than 5×10⁸ cm⁻². The dislocation density of the drift layer 25 is preferably no less than 1×10⁸ cm⁻² and no greater than 3×10⁸ cm⁻². The dislocation-density control layer 50 shown in FIG. 5C may be formed between the buffer layer 15 and the semiconductor operating layer 20. The dislocation-density control layer 50 can control the dislocation densities of the semiconductor operating layer 20 and the drift layer 25. The dislocation-density control layer 50 may be formed by layering the low-temperature growth layer 51, the roughening layer 53, and the flattening layer 55.

The semiconductor device 200 includes a recess region 25c that is a depression from the surface of the electron supplying layer 27 to the surface of the drift layer 25. A regrowth layer 29 made of group-III nitride-based compound semiconductor may be provided in the recess region 25c. The regrowth layer 29 may be formed of p-type GaN.

The semiconductor device 200 further includes the insulating film 40 made of SiO₂ on the regrowth layer 29 and the electron supplying layer 27, and the gate electrode 35 on a portion of the insulating film 40 corresponding to the recess region 25c. The semiconductor device 200 includes the source electrode 31 and the drain electrode 33 on the electron supplying layer 27 at respective sides of the recess region 25c.

With the structure described above, the semiconductor device 200 can realize the effects described below, in addition to having a high withstand voltage.

Since the electron supplying layer 27 forms a heterojunction with the drift layer 25 and has higher band gap energy than the drift layer 25, 2-dimensional electron gas (2DEG) 25g is generated on the drift layer 25 side of the heterojunction interface by intrinsic polarization and Piezo polarization. The 2DEG has high carrier (electron) concentration and high electron mobility, and can therefore decrease the ON resistance of the device.

Furthermore, the formation of the recess region 25c in this structure prevents a heterojunction from being formed at the gate portion, and therefore the 2DEG is not generated. As a result, when there is no forward bias (positive voltage) applied to the gate electrode 35, there is no channel formed that electrically connects the source electrode and the drain electrode. Accordingly, the semiconductor device 200 can perform a normally-off operation.

In the semiconductor device 200, the regrowth layer 29 is formed after the recess region 25c is formed. As a result, a level is prevented from being formed at the interface between the drift layer 25 and the insulating film 40 due to damage to the semiconductor surface during formation of the recess region 25c. As a result, a drop in mobility at the gate portion can be suppressed. The drift layer 25 may be formed at a portion where the recess region 25c is not formed, and may have a sheet carrier density no less than 1×10¹² cm⁻² and no greater than 5×10¹³ cm⁻².

The present invention is not limited to the above embodiments, and various alterations can be made without deviating from the scope of the invention. For example, the above embodiments describe a MOSFET and SBD, but the present invention can be applied to a MISFET (Metal Insulator Semiconductor FET) or to a MESFET (MEtal Semiconductor FET) as well.

Furthermore, the material for forming the semiconductor device is not limited to GaN and AlN. The semiconductor device may be formed by a nitride compound semiconductor expressed as AlₓIn_{y}Ga_{1-x-y}N, where 0≦x≦1, 0≦y≦1, and 0≦x+y≦1. The substrate may also be formed of other widely known materials such as silicon, SiC, ZnO, sapphire, or the like.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed in relation to the semiconductor device and the manufacturing method thereof shown in the claims, embodiments, or drawings can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

1. A semiconductor device comprising:
a semiconductor operating layer made of group-III nitride-based compound semiconductor; and
a first electrode and a second electrode formed on the semiconductor operating layer, wherein
sheet carrier density of the semiconductor operating layer is no less than 1×10¹² cm⁻² and no greater than 5×10¹³ cm⁻², and
dislocation density of the semiconductor operating layer is no less than 1×10⁸ cm⁻² and no greater than 5×10⁸ cm⁻².

2. The semiconductor device according to claim 1, wherein the group-III nitride-based compound semiconductor is AlₓIn_{y}Ga_{1-x-y}N, where 0≦x≦1, 0≦y≦1, and 0≦x+y≦1.

3. The semiconductor device according to claim 1, wherein
the first electrode is a Schottky electrode, and
the second electrode is an ohmic electrode.

4. The semiconductor device according to claim 1, wherein
the first electrode is a source electrode,
the second electrode is a drain electrode, and
the semiconductor device further comprises:
an insulating film that is formed on the semiconductor operating layer between the source electrode and the drain electrode; and
a gate electrode formed on the insulating film.

5. The semiconductor device according to claim 4, further comprising a regrowth layer made of the group-III nitride-based semiconductor and formed between the semiconductor operating layer and the insulating film.

6. A method of manufacturing a semiconductor device including a semiconductor operating layer made of group-III nitride-based compound semiconductor and a first electrode and a second electrode formed on the semiconductor operating layer, the method comprising:
first forming including forming, on a substrate, the semiconductor operating layer with sheet carrier density no less than 1×10¹² cm⁻² and no greater than 5×10¹³ cm⁻²; and
second forming including forming the first electrode and the second electrode on the semiconductor operating layer, wherein
the first forming further includes forming a dislocation-density control layer in the semiconductor operating layer or in a layer under the semiconductor operating layer, the dislocation-density control layer controlling dislocation density of the semiconductor operating layer to be no less than 1×10⁸ cm⁻² and no greater than 5×10⁸ cm⁻².
